(19) United States
(12) Patent Application Publication
(10) Pub. No.: US 2010/0296249 A1
(43) Pub. Date: Nov. 25, 2010

(54) MICRO PASSAGE COLD PLATE DEVICE FOR A LIQUID COOLING RADIATOR

(75) Inventor: JI LI, Beijing (CN)

Correspondence Address: G. LINK CO., LTD, 3550 BELL ROAD, MINOOKA, IL, 60447, US

(73) Assignee: Beijing AVC Technology Research Center Co., Ltd., Beijing (CN)

(21) Appl. No.: 12/468,428

(22) Filed: May 19, 2009

(51) Int. Cl. H05K 7/20

(52) U.S. Cl. 361/700; 361/699

(57) ABSTRACT

A micro passage cold plate device for a liquid cooling radiator includes a upper cover and a lower plate. The upper cover has a working medium inlet at a side thereof and a working medium outlet at another side thereof. The inlet and outlet are trumpet-shaped such that the working medium expansively enters the cold plate gradually and leaves the cold plate with a reduced way gradually. Hence, the cold plate provides an even distribution of temperature, a lower thermal resistance and a better heat dissipation performance such that the stability of the two-state flow of the working medium is enhanced for heat dissipation device in the field of electronic field.

### BACKGROUND OF THE INVENTION

1. Field of the Invention

The present invention is related to a heat dissipation device in the field of electronic products and particularly to a liquid cooling heat dissipation device with phase change of the working medium between the liquid and vapor.

2. Brief Description of the Related Art

Currently, the heat dissipation for the high performance electronic products mostly is employed with the liquid cooling type device. Referring to FIG. 1, the conventional liquid cooling device comprises a cold plate 1, a pump 2, a fin radiator 3 and a soft hose connecting with the previous parts. The cold plate 1 contacts the heat source, which is the electronic core chip such as the CPU, and the pump 2 drives the liquid to pass through the cold plate 1 and absorb the heat. The heat is released to the open air by means of the fin radiator 3 and the cooled liquid returns to pass through the cold plate 1. The preceding operation is cycled again and again, and the heat from the core chip is removed continuously. The fin radiator 3 can be cooled with the natural air or the air with a forced fan. The cold liquid can be the pure water after the ions are removed, the pure water with antifreezing liquid or another liquid mixture such as R134a.

The state of the working medium for the conventional liquid cooling radiator is unchanged during the cooling cycle. That is, the working medium in the heat dissipation device is always liquid regardless it is heated up or cooled down although the preceding way of the heat dissipation has the advantages such as low thermal resistance, great heat transfer capacity and long transmission distance. However, due to the limitation of the material of the cold plate, the thermal resistance being incapable of lowering further with respect to higher absorbed temperature of the liquid, and a high temperature gradient in the cold plate, it results in the electronic core chip contacting the cold plate providing the temperature unevenly. In this way, a thermal stress is created unexpectedly. Besides, the driving force for the liquid is constant with the thermal resistance of the liquid being unchanged is unable to satisfy the heat dissipation need of the future electronic core chip. Especially, it is hard for the liquid to cool the heat spots effectively, the high heat flex leads noise from the fan, and the life span of the pump meets a great challenge.

It can be understood from the description of the art that the conventional liquid cooling heat dissipation device still has deficiencies and inconveniences in structure and in use. In order to solve the problems existing in the liquid cooling heat dissipation device, the related suppliers have endeavored to the solutions. But, it has been long time that no proper design for the liquid cooling radiator is developed. Thus, it is one of the subjects worth us to investigate and develop a new liquid cooling device with low thermal resistance and high heat dissipation performance.

### SUMMARY OF THE INVENTION

In order to overcome the deficiencies the conventional liquid cooling heat dissipation device confronts, the main object of the present invention is to provide a micro passage cold plate for a liquid cooling radiator, which is capable of providing an even distribution of temperature, having lower thermal resistance with better heat dissipation performance, such that the flow stability of the two-phase flow working medium can be enhanced and favorable for the use.

The micro passage cold plate of the present invention is characterized in that a micro passage cold plate for a liquid cooling radiator includes a upper cover and a lower plate, which is joined to the upper cover; a medium inlet is disposed at a side of the top surface of the upper cover and a medium outlet is disposed at another side of the top surface of the upper cover; the inlet and outlet are provided with a trumpet-shaped portion respectively such that the medium expansively enters the cold plate gradually and leaves the cold plate with a reduced way gradually.

Further, a liquid storage zone is disposed at the inlet, a vapor discharge zone is disposed at the outlet, and a micro passage zone is disposed between the liquid storage zone and the vapor discharge zone. Two ends of the micro passage zone communicate with the liquid storage zone and the vapor discharge zone respectively. Besides, the vapor discharge zone and the liquid storage zone are a chamber respectively, and the micro passage zone is a passage provided with a plurality of communicating grids. The connection of the liquid storage zone to the micro passage zone has a nozzle structure and the connection of the vapor discharge zone to the micro passage zone is a straight through structure. It is appreciated that comparing to the prior art, the micro passage cold plate for a liquid cooling radiator according to the present invention has the following advantages:

(1) the trumpet-shaped inlet and outlet in the cold plate decrease the flow resistance of the working medium;

(2) the large liquid storage zone with the nozzle structure disposed before the micro passage zone is capable of avoiding the phenomenon of the working medium flowing unevenly occurring in the prior art;

(3) the nozzle structure of the liquid storage zone enables the working medium to enter the micro passage zone with the greatest flow velocity such that the vapor created from the working medium in the micro passage zone is resisted to flow backward;

(4) the micro passage zone has a long distance from the heating area of the core chip, that is, the micro passage zone is longer than the length of core chip, and the longer distance of the micro passage zone is helpful for resisting the unstable phenomenon resulting from the vapor flowing backward. The reason is in that when the working medium changes the state thereof to the vapor from the liquid in the micro passage zone, the vapor is incapable of moving back to the liquid storage zone and it causes a liquid-vapor interface with a half-moon-shaped surface. According to Laplace's equation, a capillary attraction is created at the half-moon surface and the magnitude of the capillary attraction depends upon the surface tension and the radius of the half-moon surface. Further, magnitude of the radius of the half-moon surface depends upon the cross-section of the micro passage and the smaller the cross-section of the micro passage is, the greater the capillary attraction is. As a result, the strong capillary attraction urges the liquid to move toward the outlet and resists the vapor to move backward. In addition, the longer micro passage zone is capable of stabilizing the movement of the vapor such that the liquid can flow steadily from the inlet to the outlet; and

(5) the working medium changing the state thereof to the vapor from the liquid is performed with vaporizing latent heat and the temperature of the working medium little increases such that the integral thermal resistance of the cold plate decreases apparently and the temperature of the electronic core chip is distributed much evenly.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a perspective view of the conventional structure of the liquid cooling radiator;

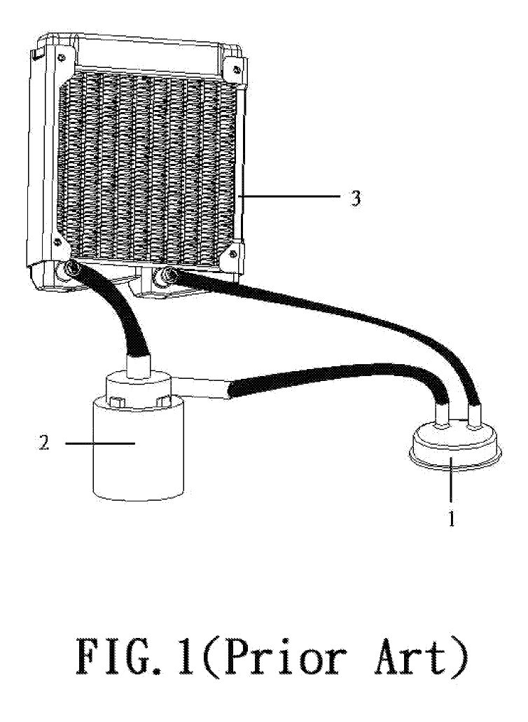

FIG. 2 is a perspective view of a micro passage cold plate device for a liquid cooling radiator according to the present invention;

FIG. 3A is a perspective view of the first embodiment of the cold plate according to the present invention;

FIG. 3B is a top view of the cold plate shown in FIG. 3A;

FIG. 3C is a sectional view along line 3C shown in FIG. 3B;

FIG. 3D is a sectional view along line 3D shown in FIG. 3B;

FIG. 4A is a perspective view of the lower plate shown in FIG. 3A;

FIG. 4B is a top view of the lower plate shown in FIG. 4A;

FIG. 4C is a sectional view along line 4C shown in FIG. 4B;

FIG. 5A is a perspective view of the second embodiment of the cold plate according to the present invention;

FIG. 5B is a top view of the cold plate shown in FIG. 5A;

FIG. 5C is a sectional view along a line 5C shown in FIG. 5B;

FIG. 5D is a sectional view along a line 5D shown in FIG. 5B;

FIG. 6 is a perspective view of the lower plate shown in FIG. 5A;

FIG. 7A is a perspective view of the second embodiment of the cold plate according to the present invention;

FIG. 7B is a top view of FIG. 7A;

FIG. 7C is a sectional view along the line 7C shown in FIG. 7B;

FIG. 7D is a sectional view along the line 7D shown in FIG. 7B;

FIG. 8 is a perspective view of the lower plate shown in FIG. 7A; and

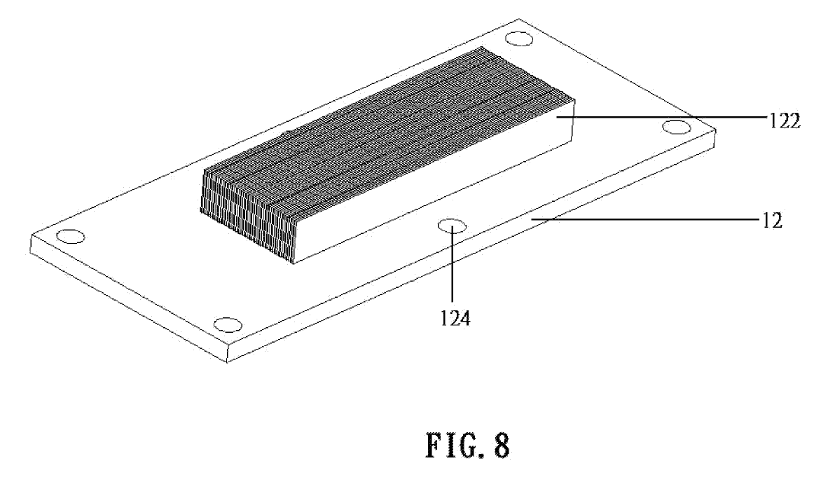

FIG. 9 is a sectional view illustrating the application of the cold plate according to the present invention.

### DETAILED DESCRIPTION OF THE INVENTION

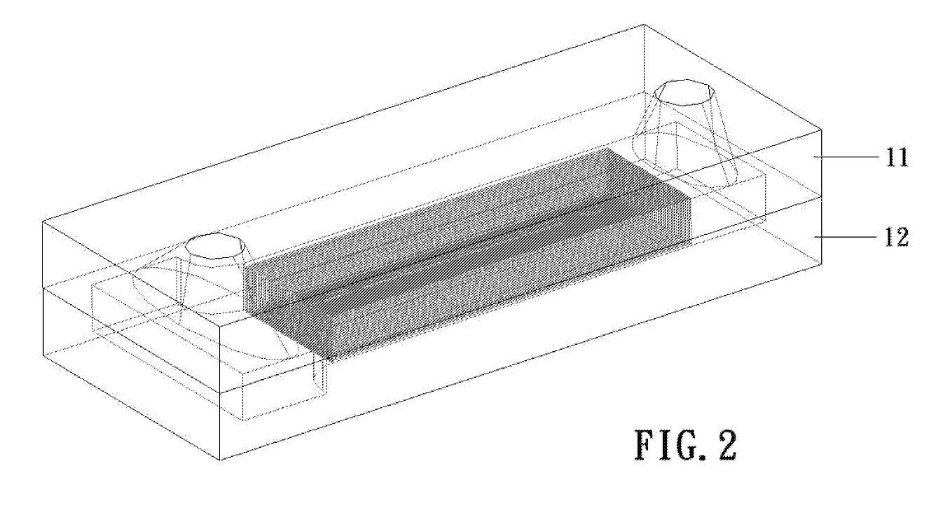

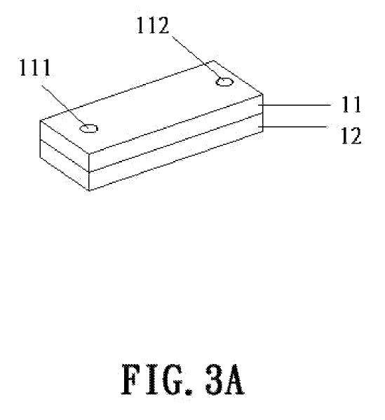

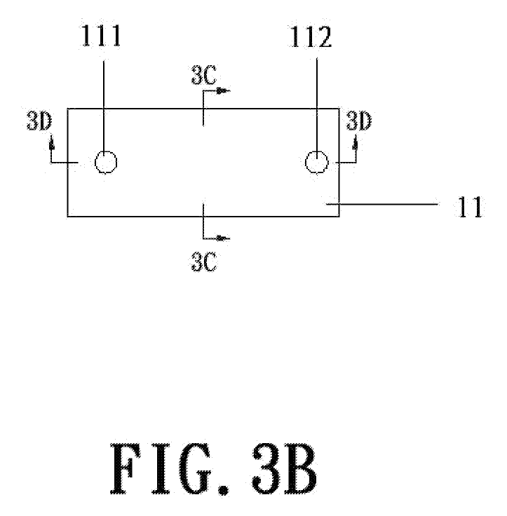

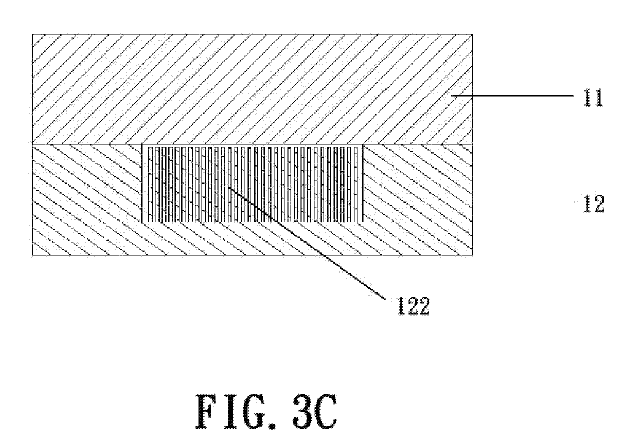

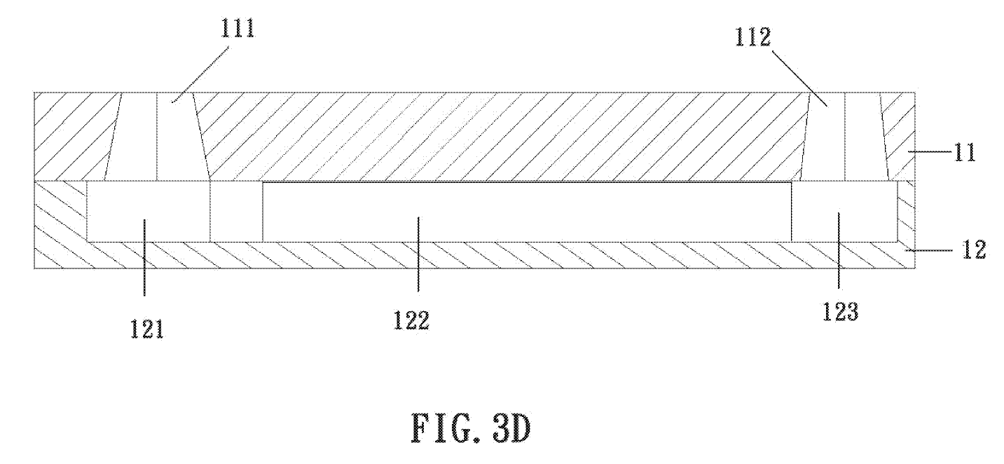

Referring to FIGS. 2 and 3A, a micro passage cold plate 1 for a liquid cooling radiator is composed of an upper cover 11 and a lower plate 12. The upper cover 11 has a working medium inlet 111 at a side thereof and has a working medium outlet 112 at another side thereof opposite to the inlet 111. The inlet 111 and the outlet 112 extend inward with a trumpet-shaped portion respectively such that the medium expansively enters the cold plate gradually and the medium leaves the cold plate 1 with a reduced way gradually.

The upper cover 11 and the lower plate 12 are made of the metal such as copper or aluminum or nonmetal such as silicon. The working medium can be the water, acetone, methanol, liquid ammonia or Freon such as R134a depending on the use.

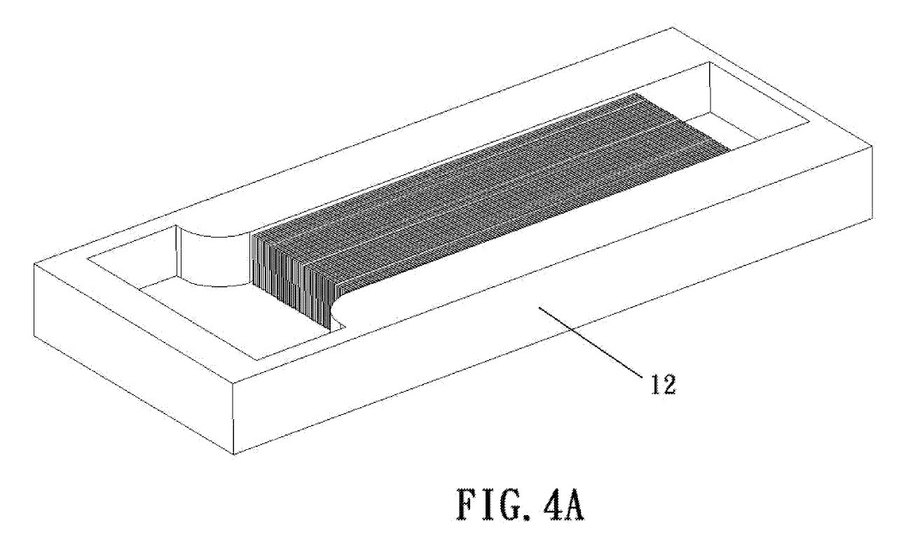

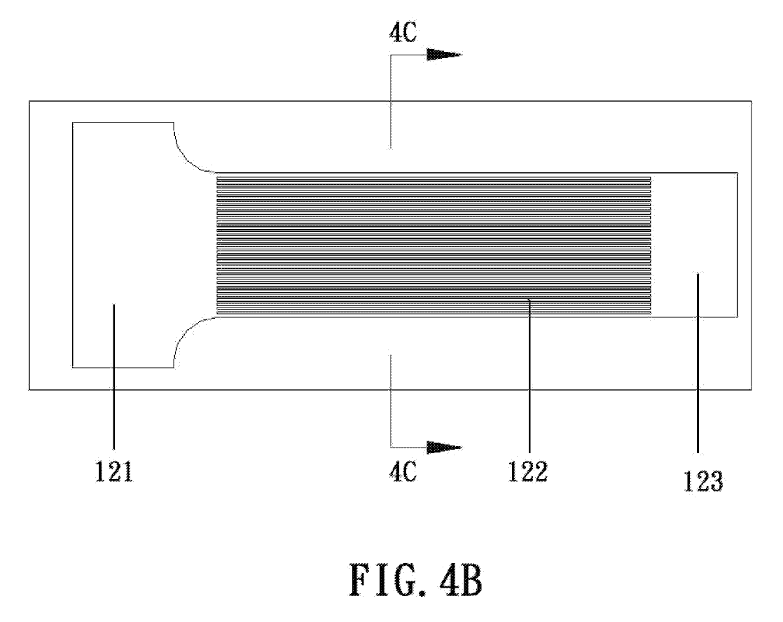

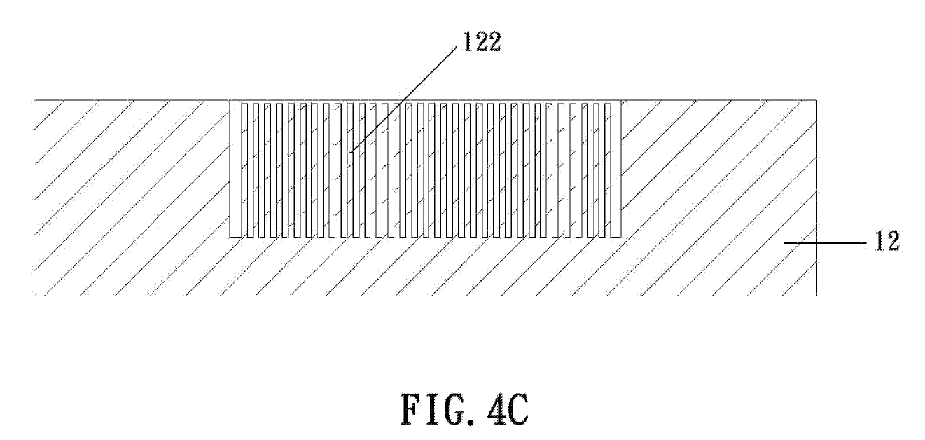

Referring to FIGS. 3A, 3B, 3C and 3D, the first embodiment of the cold plate structure for a liquid cooling radiator according to the present invention provide a lower plate 12 made of silicon and the upper cover 11 is made of silicon or quartz. The lower plate 12 is bonded to the upper cover 11 as a single piece. The upper cover 11 is formed with the trumpet-shaped inlet 111 and outlet 112 by means of the quartz being treated with the isotropic wet etching. The trumpet-shaped inlet 111 and outlet 112 are flush with the top surface of the upper cover 11. Further, the lower plate 12 is disposed with a liquid storage zone 121 next to the inlet 111 and a vapor discharge zone 123 next to the outlet 112. A micro passage zone 122 is disposed between the liquid storage zone 121 and the vapor discharge zone 123 to communicate with the liquid storage zone 121 and the vapor discharge zone 123. The liquid storage zone 121 and the vapor discharge zone 123 are provided a chamber respectively. The micro passage zone 122 is formed with a plurality of grids (see FIG. 4C). The connection between the liquid storage zone 121 and the micro passage zone 122 is a structure of nozzle, which is a large passage contracting as a small passage. The connection between the micro passage zone 122 and the vapor discharge zone 123 is a straight through passage.

Referring to FIGS. 4A, 4B, 4C and 4D, the lower plate 12 in FIG. 3A is illustrated more specifically. The lower plate 12 is fabricated with the silicon is treated with DRIE (Deep Reactive Ion Etching) to obtain the liquid storage zone 121, the micro passage zone 122 and the vapor discharge zone 123.

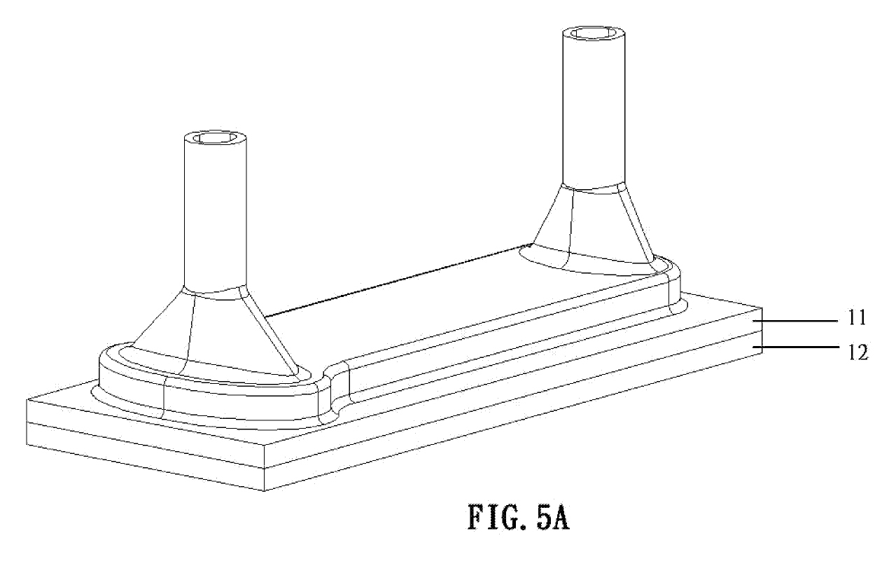

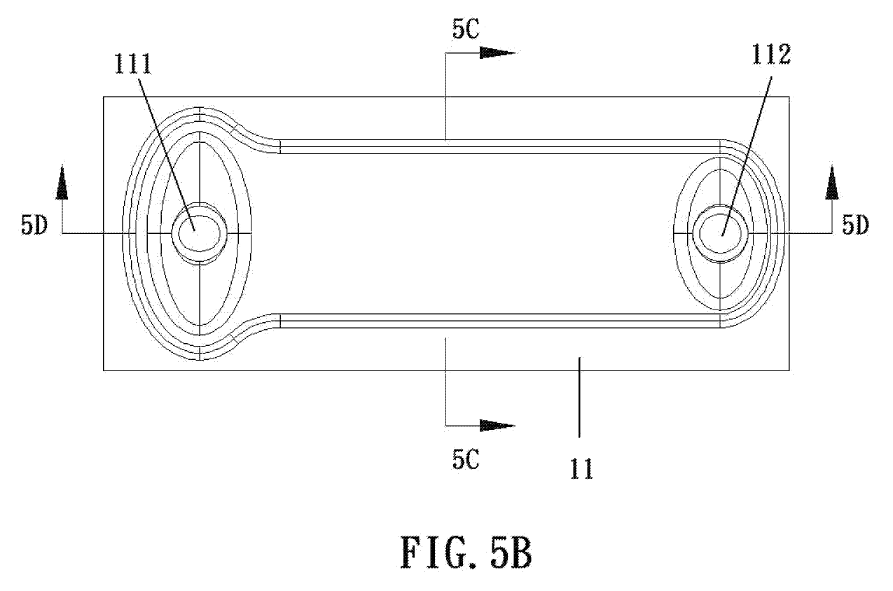

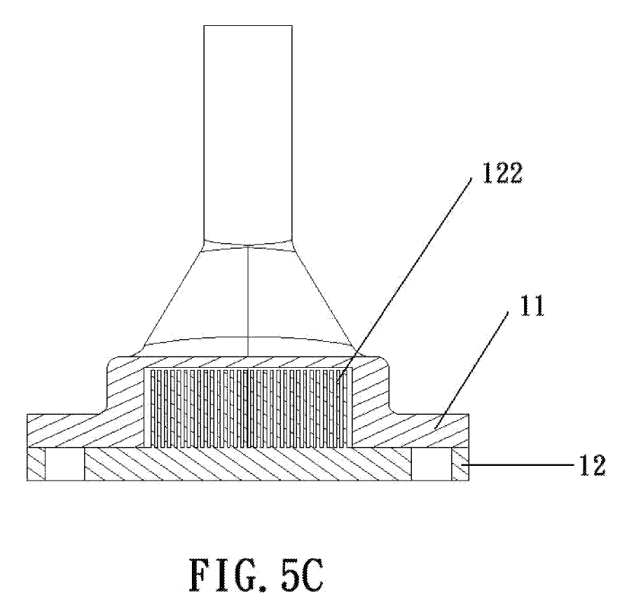

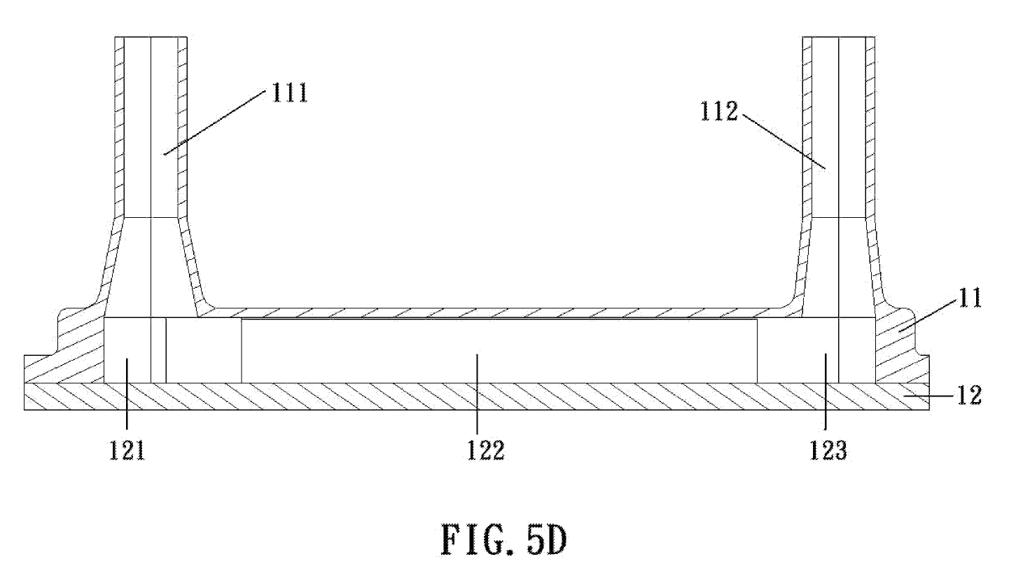

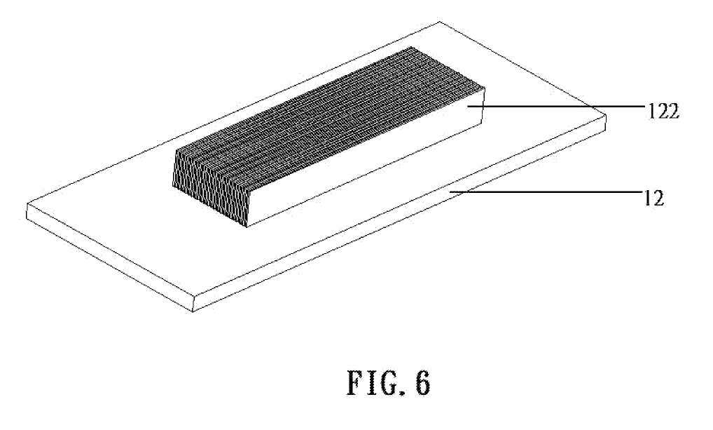

Referring to FIGS. 5A, 5B, 5C and 5D, the second embodiment of the cold plate for a liquid cooling radiator according to the present invention is illustrated. The lower plate 12 is made of a metal such as copper or aluminum, and the upper cover 11 is made of a metal the same as the lower plate 12 or different from the lower plate 12. The upper cover 11 is joined to the lower plate 12 with brazing in case of the upper cover 11 and the lower plate being made of the identical metal. The upper cover 11 is joined to the lower plate 12 with soldering in case of the upper cover 11 and the lower plate being made of different metals. The upper cover 11 is fabricated with the computer numerical control (CNC) machine, the die casting machine or the metal injection module machine to work the trumpet-shaped inlet 111 and outlet 112, the liquid storage zone 121 with the nozzle structure and the vapor discharge zone 123 with straight through structure. The lower plate 12 shown in FIG. 5A is specifically illustrated in FIG. 6 and the micro passage 122 shown in FIG. 6 can be formed with a plurality of skived fins.

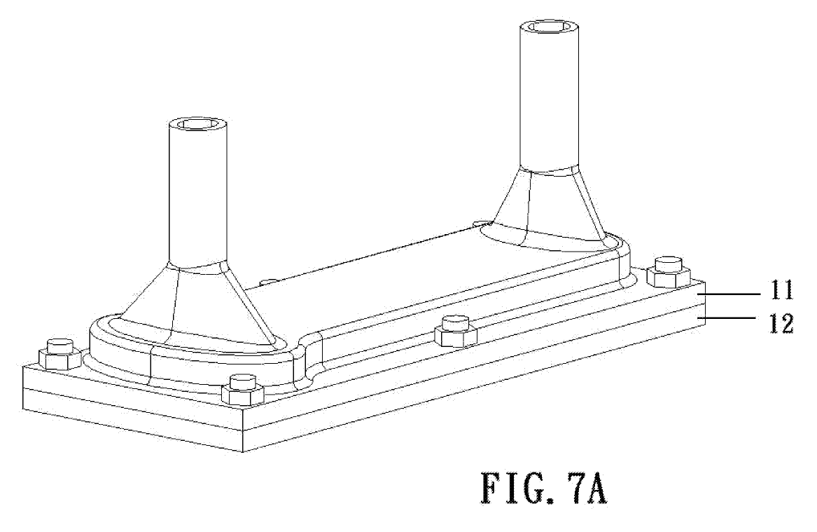

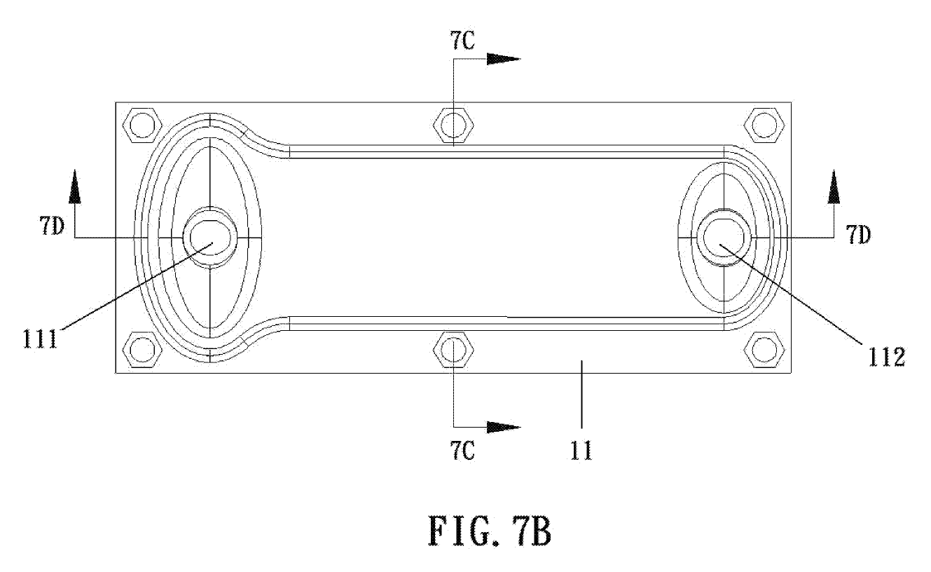

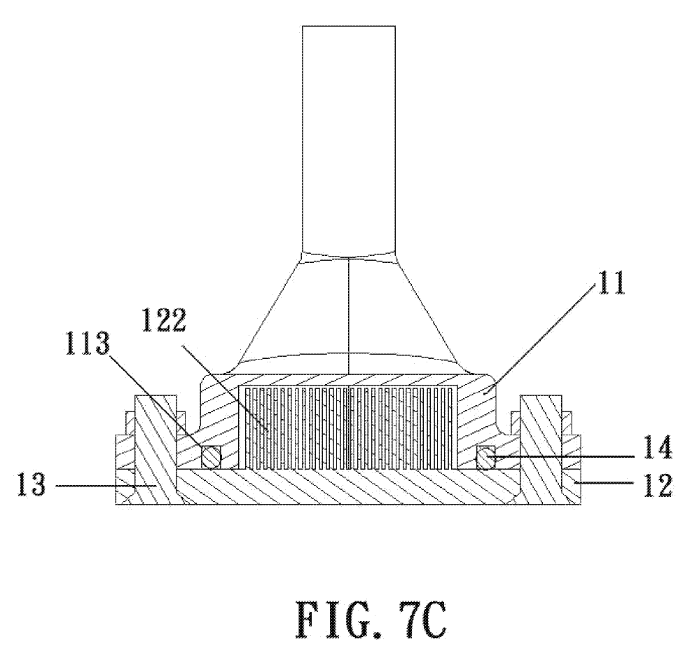

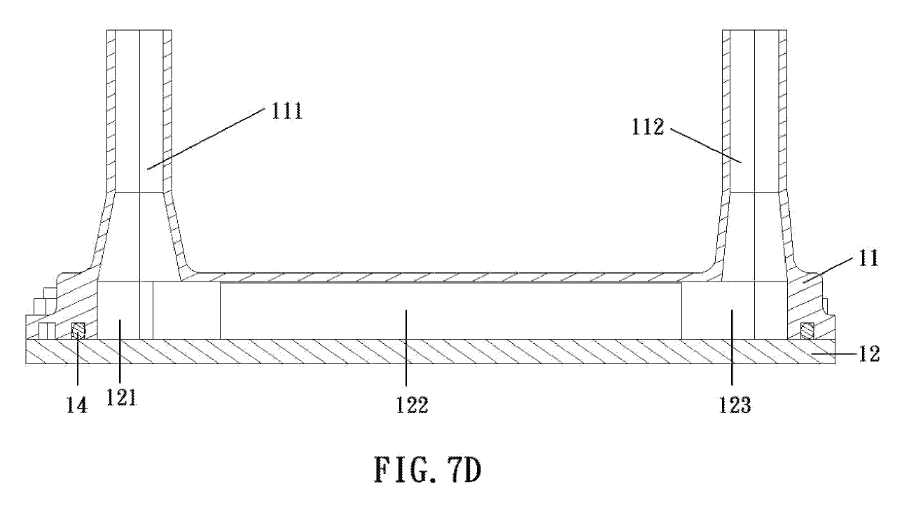

Referring to FIGS. 7A, 7B, 7C and 7D, the third embodiment of the micro passage for a liquid cooling radiator according to the present invention is illustrated. The lower plate 12 is made of a metal such as copper or aluminum and the upper cover 11 is made of a metal or plastics. The lower plate 12 is attached to the upper cover 12 tightly with screws 13, and, in order to seal the cold plate tightly, an O-ring seal 14 is disposed between the upper cover 11 and the lower plate 12. The trumpet-shaped inlet 111 and outlet 112 extend outward the top surface of the upper cover 11. The upper cover 111 can be fabricated by means of the plastics injection mold or the metal injection module such that the trumpet-shaped inlet 111 and outlet 112, the liquid storage zone 121 with the nozzle structure, the vapor discharge zone 123 with straight through structure, the micro passage zone and the groove 113 for receiving the O-ring seal 14 can be formed properly. The lower plate 12 shown in FIG. 7A is illustrated specifically. The micro passage 122 can be formed with skived fins and the threaded holes 124 for engaging with the screws 13 can be formed with machining.

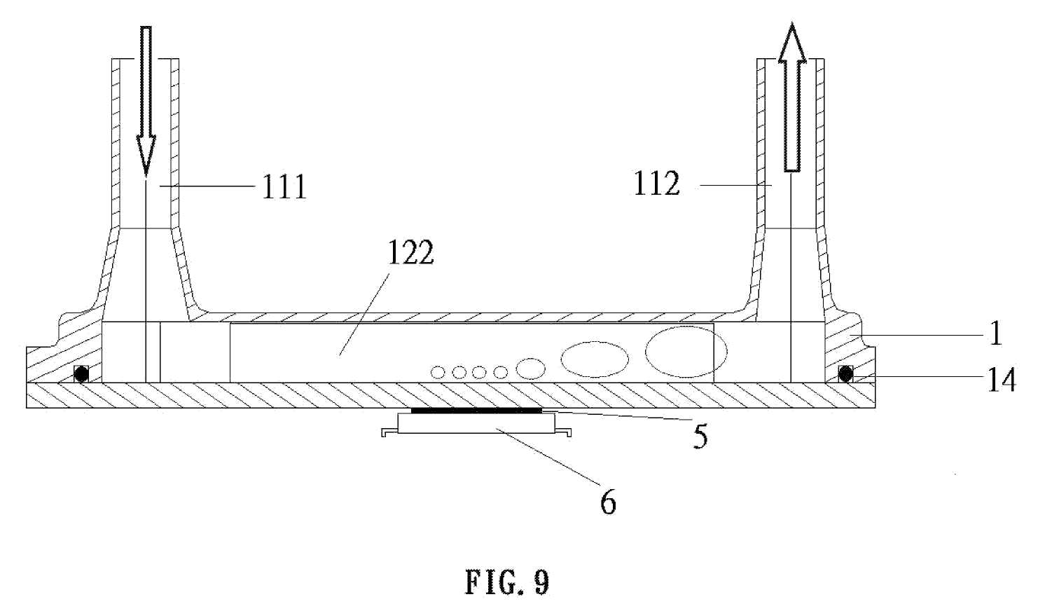

Referring FIG. 9, an example of the application of the micro passage for a liquid cooling radiator is illustrated. The liquid cooling device, which carries the state changeable working medium, includes a fin type radiator, a pump and a soft hose (not shown). The cold plate 1 passes through an interface layer of guiding heat material 5 to connect with an electronic core chip 6. The heat generated by the guiding heat material 5 transfers to the bottom surface of the lower plate 12. The heat transfers to the micro passage zone 122 and the working medium flows through the heating zone of the micro passage core chip to absorb the heat such that the working medium changes to the state of the vapor from the state of the liquid. The working medium with liquid-vapor mixture is driven by the pump (including the function of the capillary attraction previously mentioned) to flow toward the direction of the arrow shown in FIG. 9 and carry the heat coming from the lower plate 12 to the open air via the air cooling radiator. Then, the vapor is liquefied and recycled to the cold plate 1. The cycle for the working medium is operated repeatedly. It is noted that the cold plate 1 employed in the application is the third embodiment.

The micro passage for a liquid cooling radiator according to the present invention is appropriate for the heat dissipation in the field of the electronics.

While the invention has been described with referencing to the preferred embodiments thereof, it is to be understood that modifications or variations may be easily made without departing from the spirit of this invention, which is defined by the appended claims.

What is claimed is:

1. A micro passage cold plate for a liquid cooling device comprising:
an upper cover, wherein a side at a top thereof is disposed with a working medium inlet and another side thereof is disposed with a working medium outlet; and
a lower plate joined to said upper cover;
characterized in that said inlet and said outlet extend inward a trumpet-shaped portion respectively such that the working medium expansively enters said cold plate gradually and leaves said cold plate with a reduced way gradually.

2. The micro passage cold plate for a liquid cooling device as defined in claim 1, wherein a liquid storage zone is disposed at said inlet, a vapor discharge zone is disposed at the outlet and a micro passage zone is disposed between said liquid storage zone and said vapor discharge zone.

3. The micro passage cold plate for a liquid cooling device as defined in claim 2, wherein said liquid storage zone and said vapor discharge zone are a chamber respectively and said micro passage zone is a grid-shaped passage with said liquid storage zone having a nozzle structure to communicate with said micro passage zone and said vapor discharge zone having a straight through pipe structure to communicate with said micro passage zone.

4. The micro passage cold plate for a liquid cooling device as defined in claim 1, wherein said lower plate and said upper cover are made of semiconductor material and bonded as a single piece, and said trumpet-shaped inlet and outlet are fabricated to be flush with said top surface of said upper cover.

5. The micro passage cold plate for a liquid cooling device as defined in claim 2, wherein said lower plate and said upper cover are made of semiconductor material and bonded as a single piece, and said trumpet-shaped inlet and outlet are fabricated to be flush with said top surface of said upper cover.

6. The micro passage cold plate for a liquid cooling device as defined in claim 1, wherein said lower plate and said upper cover are made of a metal and welded as a single piece of said cold plate; and said trumpet-shaped inlet and outlet are machined to extend outward the top surface of said upper cover.

7. The micro passage cold plate for a liquid cooling device as defined in claim 2, wherein said lower plate and said upper cover are made of a metal and welded as a single piece of said cold plate; and said trumpet-shaped inlet and outlet are machined to extend outward the top surface of said upper cover.

8. The micro passage cold plate for a liquid cooling device as defined in claim 1, wherein said lower plate, which is made of a metal, and said upper cover, which is made of a metal or nonmetal, engage with each other tightly with a plurality of screws; and said trumpet-shaped inlet and said trumpet-shaped outlet are fabricated with a plastics injection mold or machining to extend outward the top surface of said upper cover.

9. The micro passage cold plate for a liquid cooling device as defined in claim 1, wherein said lower plate, which is made of a metal, and said upper cover, which is made of a metal or nonmetal, engage with each other tightly with a plurality of screws; and said trumpet-shaped inlet and said trumpet-shaped outlet are fabricated with a plastics injection mold or machining to extend outward the top surface of said upper cover.

10. The micro passage cold plate for a liquid cooling device as defined in claim 6, wherein a O-ring seal is disposed between said upper cover and said lower plate.

11. The micro passage cold plate for a liquid cooling device as defined in claim 7, wherein a O-ring seal is disposed between said upper cover and said lower plate.
